(19) United States
(12) Patent Application Publication
(10) Pub. No.: US 2016/0233200 A1
(43) Pub. Date: Aug. 11, 2016

(54) Production of an Optoelectronic Component

(71) Applicant: OSRAM Opto Semiconductors GmbH, Regensburg (DE)

(72) Inventors: Markus Pindl, Tegernheim (DE); Simon Jerebic, Tegernheim (DE); Tobias Geltl, Pförring (DE)

(73) Assignee: OSRAM Opto Semiconductors GmbH, Regensburg (DE)

(21) Appl. No.: 15/025,759

(22) PCT Filed: Oct. 15, 2014
(86) PCT No.: PCT/EP2014/072007

§ 371 Date: Mar. 29, 2016

(30) Foreign Application Priority Data
Oct. 15, 2013 (DE) 10 2013 220 790.5

(51) Int. Cl. H01L 25/075; H01L 33/62; H01L 33/50; H01L 33/60; H01L 21/66; H01L 33/54

(52) U.S. Cl. CPC H01L 25/0753; H01L 22/26; H01L 33/54; H01L 33/507; H01L 33/60; H01L 33/62; H01L 2933/0041; H01L 2933/005; H01L 2933/0058; H01L 2933/0066

(57) ABSTRACT

A method for producing an optoelectronic component is disclosed. In various embodiments, the method includes arranging a plurality of optoelectronic semiconductor chips on a carrier and commonly compressing separate molding compounds in areas of the optoelectronic semiconductor chips, wherein separate molded bodies are formed in the areas of the optoelectronic semiconductor chips.

This patent application is a national phase filing under section 371 of PCT/EP2014/072007, filed Oct. 14, 2014, which claims the priority of German patent application 10 2013 220 790.5, filed Oct. 15, 2013, each of which is incorporated herein by reference in its entirety.

### TECHNICAL FIELD

The invention relates to a method for producing an optoelectronic component.

### BACKGROUND

An optoelectronic component may comprise an optoelectronic semiconductor chip for generating a light radiation and at least one phosphor for radiation conversion. The phosphor(s) may convert part of the light radiation of the semiconductor chip into one or a plurality of other light radiations. In this way, a mixed radiation may be generated, the color locus of which is dependent on the ratio of converted to unconverted radiation. In one known configuration, a planar layer serving as a conversion body and comprising the at least one phosphor is arranged on the semiconductor chip.

In one known production method, a plurality of optoelectronic semiconductor chips are arranged on a carrier. A plurality of conversion layers produced separately from the semiconductor chips are arranged on the semiconductor chips. Areas between the semiconductor chips and around the latter are potted with a reflective compound. This arrangement may subsequently be singulated.

In order to prevent front sides of the phosphor layers from being wetted during the application of the reflective potting compound, a configuration comprising sharp front-side edges is striven for. The reflective potting compound may be stopped at such front edges on account of the surface tension. Phosphor layers comprising such a property may be produced by the singulation of a ceramic starting layer. However, the production of ceramic phosphor layers is associated with a high outlay.

A further requirement is low color locus scattering. For this purpose, phosphor layers are subjected to a measurement after production in order to detect the conversion properties, and are sorted. Prior to arrangement on semiconductor chips, phosphor layers are selected on the basis thereof in order to be able to produce components whose light radiation comprises a predefined color locus. This procedure is likewise associated with a high outlay.

### SUMMARY

In accordance with one aspect of the invention, a method for producing an optoelectronic component is proposed. The method involves arranging a plurality of optoelectronic semiconductor chips on a carrier. Provision is furthermore made of common compressing of separate molding compounds in the area of the optoelectronic semiconductor chips. In this way, separate molded bodies are formed in the area of the optoelectronic semiconductor chips.

In the method, separate molded bodies assigned to the individual semiconductor chips are formed directly at the location of the semiconductor chips. This is done by a corresponding molding compound being provided in the area of each semiconductor chip and the molding compounds being jointly compressed. The optoelectronic semiconductor chips that may be designed for generating a light radiation may be encapsulated by the molded bodies formed in this way.

The method may be carried out with a low outlay. The molded bodies that are present in the area of the semiconductor chips and are arranged on the semiconductor chips may comprise sharp edges in the area of a front side, on account of the compressing of the molding compounds. This proves to be expedient with regard to a potting process subsequently carried out, if appropriate.

The molded bodies formed by compressing of the molding compounds may comprise a shape that opens or widens at least partly in the direction of a front side. Such a shape fosters the production of reflectors.

The carrier with the optoelectronic semiconductor chips and molded bodies may constitute an optoelectronic component or package. It is also possible for such an arrangement to serve as an intermediate product, and for further method steps to be carried out afterward. Consideration is given to a singulation process, for example. In this sense the method may be used for jointly producing a plurality of optoelectronic components which are separated from one another by the singulation. The singulation may be carried out in such a way that an optoelectronic component formed thereby comprises a part of the carrier, a semiconductor chip and an associated molded body in the area of the semiconductor chip. It is also possible for an optoelectronic component formed by the singulation to comprise a part of the carrier and a plurality of optoelectronic semiconductor chips and molded bodies.

Further possible embodiments of the method are described in greater detail below.

Consideration may be given, for example, to the case where the molding compounds are phosphor compounds. The molded bodies formed by the compressing of the phosphor compounds may thus be phosphor bodies. In this embodiment of the method, separate phosphor bodies assigned to the individual semiconductor chips are formed directly at the location of the semiconductor chips, instead of phosphor layers being produced separately and arranged on optoelectronic semiconductor chips. In this embodiment of the method, this is carried out by means of a corresponding phosphor compound being provided in the area of each semiconductor chip and the phosphor compounds being jointly compressed. The optoelectronic semiconductor chips may be encapsulated by the phosphor bodies formed in this way.

During the operation of an optoelectronic component produced in this way, a semiconductor chip may generate a light radiation. A radiation conversion of the light radiation generated by the semiconductor chip may be brought about with an associated phosphor body. A mixed radiation may be generated by the superimposition of converted and unconverted radiation portions, which mixed radiation may be emitted via the phosphor body. For this purpose, the phosphor compounds and the phosphor bodies formed therefrom comprise at least one conversion material for radiation conversion.

The ratio of converted to unconverted radiation, and thus the color locus of a light radiation which may be generated by a semiconductor chip equipped with a phosphor body, depends on how strongly or how far a phosphor compound forming the phosphor body is compressed. Since all the phosphor compounds are compressed jointly, only low or even negligible color locus scattering may be present in the case of the semiconductor chips provided with the phosphor bodies. Complex sorting does not take place here.

The optoelectronic semiconductor chips may be light emitting diode or LED chips, for example. The latter may be designed, for example, for generating a blue light radiation. The phosphor bodies may be designed to convert part of the blue light into one or a plurality of light radiations, for example, in the green to red spectral range. A white mixed radiation, for example, may be generated in this way.

The method may also be carried out with molding compounds that do not comprise any conversion material for radiation conversion. This will be discussed in even greater detail further below. Hereinafter, further embodiments of the method are described in which both phosphor-filled and phosphor-free molding compounds may be used.

The compressing of the molding compounds may be carried out with the aid of a suitable tool. This may be, for example, a mold tool of a compressing molding installation. The tool may comprise two tool parts or tool halves which are moved relative to one another for the compressing of the molding compounds and are thereby compressed. The carrier with the optoelectronic semiconductor chips may be arranged on a tool part and, if appropriate, held by the tool part. For the compressing, just one tool part may be moved or both tool parts may be moved jointly relative to one another.

In a further embodiment of the method, the molding compounds are applied on the carrier in the area of the optoelectronic semiconductor chips prior to the compressing is carried out. As a result, the molded bodies may be produced with a high reliability at the location of the semiconductor chips. The molding compounds may be applied in such a way that the semiconductor chips are encapsulated or surrounded by the molding compounds. The semiconductor chips may be arranged in a predefined grid on the carrier.

In a further embodiment, which may be taken into consideration in association with the above-described application of the molding compounds on the carrier, the compressing is carried out using a tool part comprising a planar shape in the area of a side provided for the compressing of the molding compounds. The carrier with the semiconductor chips, as was indicated above, may be arranged on a further tool part. By means of relative movement of the two tool parts, the molding compounds may be compressed between the carrier and the tool part comprising the planar side. In this case, the molding compounds may be pressed flat and spread out laterally. The molded bodies formed in this way may comprise a planar front side and sharp front edges. The tool part comprising the planar side may be, for example, part of a suitable flat tool, for example, of a flat mold tool of a compressing molding installation.

In a further embodiment of the method, the molding compounds are applied on an auxiliary carrier prior to the compressing. In this case, the molding compounds may be applied on the auxiliary carrier in a predefined grid corresponding to a grid of the semiconductor chips on the carrier. For the compressing, the auxiliary carrier provided with the molding compounds and the carrier provided with the semiconductor chips may be arranged on corresponding tool parts of a tool. The two tool parts may subsequently be moved relative to one another in order to compress the molding compounds between the auxiliary carrier and the carrier. In the context of this process, the molding compounds may be provided at the location of the semiconductor chips by the semiconductor chips being introduced or dipped into the molding compounds. This embodiment, in particular, affords the possibility that the molded bodies formed by the compressing of the molding compounds comprise a shape widening at least partly in the direction of a front side.

The auxiliary carrier may comprise a planar shape on the side on which the molding compounds are arranged and with which the molding compounds are compressed. As a result, the molding compounds may be pressed flat, in a manner comparable with the above-described use of a tool part comprising a flat side, with the result that molded bodies comprising a planar front side and sharp front edges are formed.

The compressing of the molding compounds may also be carried out in such a way that a certain shape is additionally imparted to the molded bodies formed in this case. A shaping may be achieved by virtue of the fact that a component part used for the compressing comprises a side comprising a suitable structure.

By way of example, it is possible for the auxiliary carrier used in one embodiment of the method to comprise a structure, instead of a planar surface, in the area of a side provided for the compressing of the molding compounds. Since the molding compounds are arranged on the auxiliary carrier prior to the compressing, the molding compounds may in this case be positioned as accurately as possible in relation to the structure of the auxiliary carrier.

The structure may be cavities, for example, which are provided at the side used for the compressing of the molding compounds. The molding compounds may be arranged on the auxiliary carrier prior to the compressing in such a way that the molding compounds are situated in the area of or within the cavities. In the context of the compressing, the carrier and the auxiliary carrier may be moved relative to one another, as a result of which the semiconductor chips are introduced into the cavities and thus into the molding compounds. Furthermore, the molding compounds may conform to the shape of the cavities. Provision may be made for the molding compounds in this case to fill the cavities only partly, rather than completely.

Alternatively, consideration may be given to a structure comprising other structure elements to obtain a shaping or conforming of molding compounds. They include elevations or depressions, for example. Such structure elements may furthermore be configured in a curved fashion, for example. In this way, it is possible to realize molded bodies comprising curved front sides which act as a lens, for example. A combination of the structure elements mentioned above is also possible, such that cavities and curved areas may be present, for example.

A structure for shaping may be provided not only on an auxiliary carrier. It is also conceivable to use for the compressing a tool part comprising a structure in the area of a side provided for the compressing of the molding compounds. For such a structure, consideration may analogously be given to the configurations described above, that is to say that the structure may comprise cavities, elevations and/or depressions, for example.

After the compressing of the molding compounds, curing of the molding compounds or of the molded bodies formed therefrom may be carried out. The molding compounds may be in a flowable, for example, pasty state beforehand such that the molding compounds may be correspondingly deformed during compressing. The shape of the molded bodies is fixed after curing.

The molding compounds may comprise a radiation-transmissive basic material and particles embedded therein. When the molding compounds are provided and compressed, the basic material is in a flowable state. The basic material may be silicone, for example.

The basic material may contain phosphor particles for radiation conversion, for example, as a result of which the molding compounds may be phosphor compounds, as indicated above. In the case of a basic material composed of silicone, the phosphor compounds may thus be present in the form of a silicone-phosphor mixture. The phosphor particles contained in the basic material may be formed from the same conversion material for radiation conversion. The basic material may also comprise a mixture of different phosphor particles that are formed from different conversion materials.

Other particles may also be embedded in the basic material. Possible examples are scattering particles, reflective particles and pigments. It is furthermore possible for the basic material to contain a mixture of different particles. By way of example, a combination of phosphor particles and scattering particles may be provided.

Light scattering may be brought about with the aid of scattering particles, which may be used, for example, for influencing the luminous properties of an optoelectronic component. If phosphor particles are additionally present, light mixing may be brought about in this way. Reflective particles may ensure that a molded or phosphor body comprises a white body color. A different body color may be brought about by the use of corresponding pigments.

As was indicated above, the method may be carried out using molding compounds which do not comprise any conversion material for radiation conversion. Such molding compounds may comprise a radiation-transmissive basic material, for example, silicone, and scattering particles, reflective particles and/or pigments. Furthermore, it is possible for the molding compounds, present in a flowable state when they are provided and compressed, to comprise no particles, but rather only a radiation-transmissive material, for example, silicone.

A further step that may be carried out in the method is removal from the mold carried out after the compressing of the molding compounds, i.e. removal of the workpiece or carrier with the semiconductor chips and molded bodies from a tool used for the compressing. When an auxiliary carrier is used, carrier and auxiliary carrier may be removed together, and the auxiliary carrier may subsequently be detached. The step of removal from the tool may be carried out after curing of the molding compounds.

In a further embodiment of the method, a reflective compound is applied on the carrier in such a way that the molded bodies are surrounded circumferentially by the reflective compound. In this case, the reflective compound is arranged in interspaces between the molded bodies. The reflective compound makes it possible that, during the operation of an optoelectronic component produced by the method, a light radiation emitted laterally by a molded body is reflected, such that emission of radiation may take place only via a front side of the relevant molded body. The reflective compound may be, for example, silicone with TiO2 particles contained therein.

As was indicated above, a molded body of an optoelectronic component may comprise a shape widening at least partly in the direction of the front side. As a result, the reflective compound or side walls of the reflective compound that are adjacent to the molded body may act as a reflector for directing light radiation in the direction of the front side. The method thus makes it possible to form integrated reflectors. Separate production of reflectors, for example, with the aid of a molding process, may therefore be omitted.

The reflective compound may, for example, be arranged on the carrier by potting and subsequently be cured. These steps may be carried out after removal from the mold or removal of the carrier from a tool used for the compressing. The molded bodies may comprise sharp front-side edges, such that the reflective compound may be potted reliably without the front sides of the molded bodies being wetted.

Alternatively, it is possible to apply the reflective compound on the carrier prior to removal from the mold. For this purpose, the reflective compound may be introduced into cavities present between the carrier, the molded bodies and a tool part used for the compressing or an auxiliary carrier, and may subsequently be cured. Such a procedure, which may involve transfer molding, likewise enables the reflective compound to be applied without the front sides of molded bodies being wetted. Afterward, the carrier provided with the reflective compound may be removed from the tool.

After the application and curing of the reflective compound, the carrier may be singulated, as indicated above.

In a further embodiment of the method, the molding compounds are compressed to a predefined material thickness. It is thereby possible to accurately define the luminous properties of an optoelectronic component. This may be taken into consideration, for example, when phosphor compounds are used. The compressing of the phosphor compounds to a predefined material thickness makes it possible to define the color locus or the color space coordinates of a light radiation which is emittable by the semiconductor chips equipped with molded or phosphor bodies.

In the abovementioned embodiment, a distance regulation may be employed, for example. In this case, tool parts of a tool used for the compressing may be moved relative to one another until a predefined distance is attained. Compressing to a defined material thickness is also possible by using spacers which provide a stop during the compressing. Such spacers may be present on the carrier, a tool part and/or an auxiliary carrier possibly used. In a configuration of a tool part or auxiliary carrier with a structure, structure elements of the structure may serve as spacers.

In a further embodiment of the method, during the compressing of the molding compounds, at least one optoelectronic semiconductor chip is operated and a light radiation emitted by the associated molding compound is detected. The luminous properties of an optoelectronic component may also be accurately predefined in this way. This may likewise be taken into consideration when phosphor compounds are used, in order to define a color locus. This makes use of the fact that even the non-cured phosphor compounds may effect a radiation conversion. The compressing leads to a shift in the ratio of converted to unconverted radiation, and thus to a color locus shift. The compressing of the phosphor compounds may be carried out until the measured light radiation comprises a color locus corresponding to a predefined color locus. In this way, all semiconductor chips of the carrier that are equipped with phosphor bodies may emit light radiations which may comprise predefined color space coordinates on average.

A higher accuracy may be obtained if, instead of one semiconductor chip, a plurality or all of the semiconductor chips of the carrier are operated and the light radiation emitted by the associated molding or phosphor compounds is detected. In order to be able to detect the light radiation, parts of a tool used for the compressing and of an auxiliary carrier possibly used may be configured such that they are radiation-transmissive at least regionally.

A compressing of phosphor compounds to a predefined material thickness and detection of a light radiation furthermore make it possible that only low color locus scattering with regard to the generatable light radiations may be present in-between a plurality of carriers processed in accordance with the method.

The advantageous embodiments and developments of the invention that have been explained above and/or are represented in the dependent claims may—apart from, for example, in cases of clear dependencies or incompatible alternatives—be employed individually or else in any desired combination with one another.

### BRIEF DESCRIPTION OF THE DRAWINGS

The above-described properties, features and advantages of this invention and the way in which they are achieved will become clearer and more clearly understood in association with the following description of exemplary embodiments which are explained in greater detail in association with the schematic drawings, in which:

FIGS. 1 to 5 show a method in which molding compounds are applied on a carrier with semiconductor chips and are compressed with the aid of a tool part for forming molded bodies, and a reflective compound is subsequently formed on the carrier;

FIGS. 6 to 10 show a further method, in which, in contrast to the method in FIGS. 1 to 5, the molding compounds are arranged on an auxiliary carrier prior to the compressing;

FIGS. 11 to 14 show a development of the method in FIGS. 6 to 10 in which an auxiliary carrier comprising curved depressions is used;

FIGS. 15 to 18 show a development of the method in FIGS. 6 to 10 in which an auxiliary carrier comprising cavities is used;

FIGS. 19 to 22 show a development of the method in FIGS. 6 to 10 in which an auxiliary carrier comprising cavities and curved depressions is used; and

FIG. 23 shows a formation of a reflective compound prior to removal from the mold.

### DETAILED DESCRIPTION OF ILLUSTRATIVE EMBODIMENTS

Embodiments of a method for producing optoelectronic components are described on the basis of the following schematic figures. In this case, processes known from semiconductor technology and from the fabrication of optoelectronic components may be carried out and customary materials in this field may be used, and so they will be discussed only in part. It is furthermore pointed out that the figures are merely of schematic nature and are not true to scale. In this sense, component parts and structures shown in the figures may be illustrated with an exaggeratedly large size or reduced size in order to afford a better understanding.

In the embodiments of the method, in each case a plurality of molded bodies 125 for optoelectronic semiconductor chips 110 are formed directly at the location of the semiconductor chips 110. This is done by virtue of the fact that separate molding compounds 120 provided in the area of the semiconductor chips 110 are jointly compressed.

The following description with reference to the figures relates to one possible configuration of the molded bodies 125 as phosphor bodies 125, with the aid of which a light radiation emitted by the semiconductor chips 110 during operation may be converted. For this purpose, phosphor-filled molding compounds 120 are used, which hereinafter are also referred to as phosphor compounds 120.

The process sequence may be referred to as a combined metering and compressing molding process. Advantages include, inter alia, a low manufacturing outlay and the possibility of accurately defining the color locus of the light radiations generatable by the components, only low color locus scattering being present.

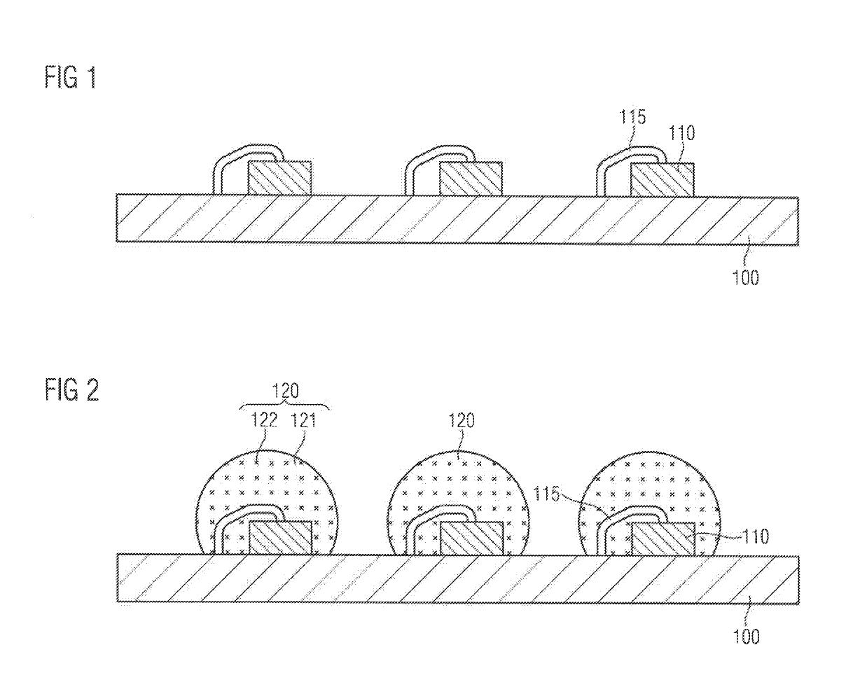

FIGS. 1 to 5 show, in a schematic lateral illustration, process steps which may be carried out in a method for producing optoelectronic components. In this case, as is shown in FIG. 1, a plurality of optoelectronic semiconductor chips 110 are arranged on a planar carrier 100. The semiconductor chips 110 are designed for emitting light radiation.

FIG. 1 shows three semiconductor chips 110, which are arranged alongside one another on the carrier 100. It is possible to provide a larger number of semiconductor chips 110 on the carrier 100. In this sense, FIG. 1 and the further figures may illustrate the carrier 100 only as excerpts. The semiconductor chips 110 may be positioned in the form of a predefined grid composed of rows and columns on the carrier 100.

Arranging the semiconductor chips 110 on the carrier 100 may comprise both mechanical fixing and electrical connection of the semiconductor chips 110. Electrical connection may be carried out with the aid of bond wires 115, as is indicated in FIG. 1. Each semiconductor chip 110 may comprise a front-side contact and a rear-side contact (not illustrated). A front-side contact of a semiconductor chip 110 may be connected to a mating contact (not shown) of the carrier 100 via a bond wire 115 in a wire bonding process. Via a rear-side contact of a semiconductor chip 110, it is possible to produce an electrical and mechanical connection of the chip 110, for example, using a solder or an electrically conductive adhesive, to a further mating contact (not shown) of the carrier 100. All of the semiconductor chips 110 may be connected to contacts of the carrier 100 in this way.

The carrier 100 serving as a substrate for the semiconductor chips 110 may comprise, besides the contacts mentioned above, further electrical structures (not shown) such as, for example, conductor tracks and terminals for an external contacting. The carrier 100 may be realized in various configurations. Consideration is given, for example, to a configuration as a printed circuit board, a ceramic carrier or a premold carrier.

The optoelectronic semiconductor chips 110 may be light emitting diode chips, in particular. The semiconductor chips 110 may be produced in the usual way and comprise component parts such as a semiconductor layer sequence comprising an active zone for generating radiation. The semiconductor chips 110 may furthermore be surface emitters, in which a substantial part of the light radiation generated may be emitted via the front side, directed upward in FIG. 1.

After the process of arranging the semiconductor chips 110, as is shown in FIG. 2, mutually separate phosphor compounds 120 are applied on the carrier 100 in the area of the semiconductor chips 110. In this case, the phosphor compounds 120 are in a flowable or pasty state. The application of the phosphor compounds 120 is carried out in such a way that the semiconductor chips 110 are encapsulated by the phosphor compounds 120. Each semiconductor chip 110 is provided with a dedicated phosphor compound 120. The bond wires 115 may be completely surrounded by the phosphor compounds 120. The phosphor compounds 120 may be applied by means of a suitable metering process. For example, dispensing with the aid of a needle metering unit is possible. The phosphor compounds 120 may comprise the shape of balls or bumps.

The phosphor compounds 120 comprise a flowable and radiation-transmissive basic or matrix material 121 and particles 122 embedded therein. The basic material 121 may be silicone, for example. The particles 122 contained in the basic material 121 may be phosphor particles 122 that are used to effect a conversion of light radiation of the semiconductor chips 110. The phosphor particles 122 comprise a suitable conversion material for this purpose. It is possible for all of the phosphor particles 122 to be formed from the same conversion material. It is also possible for the basic material 121 to contain a mixture of different phosphor particles 122 that are formed from different conversion materials. If appropriate, the particles 122 embedded in the basic material 121 may comprise further particles, for example, scattering particles.

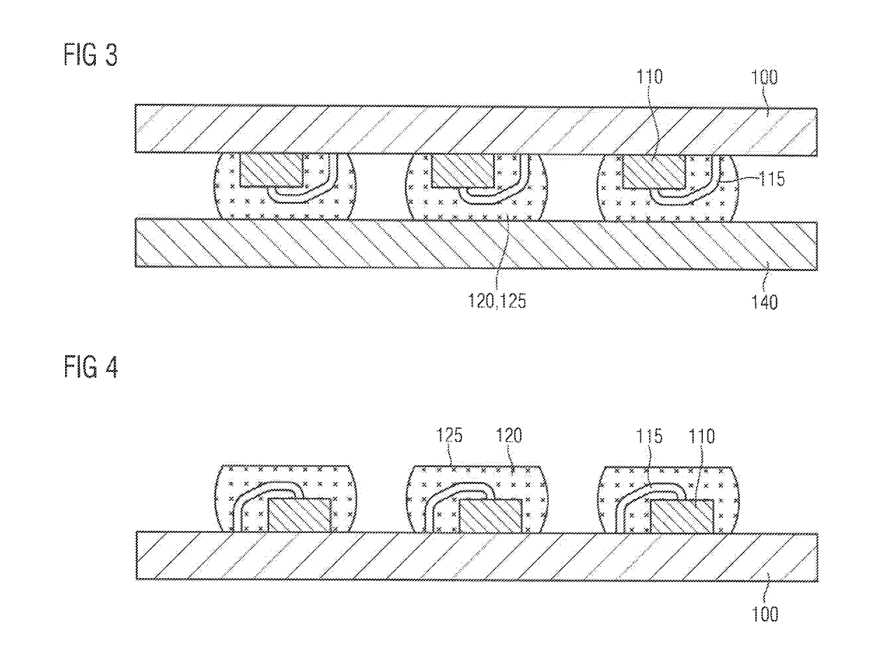

After the process of providing or metering the phosphor compounds 120 on the substrate 100, as is shown in FIG. 3, common compressing of the separate phosphor compounds 120 is carried out. As a result, phosphor bodies 125 are formed in the area of the optoelectronic semiconductor chips 110, and they are likewise present separately from one another. In the case of a component produced by the method, a phosphor body 125 serves to effect a radiation conversion of the light radiation generated by an associated semiconductor chip 110. In this case, the light radiation emitted by a semiconductor chip 110 on the front side may be distributed by scattering and reflection within the phosphor compound 120 or the phosphor body 125 formed therefrom. A mixed radiation may be generated by a superimposition of converted and unconverted radiation, and may be emitted via the phosphor body 125.

It is possible, for example, for the semiconductor chips 110 to generate a blue light radiation which is partly converted into one or a plurality of light radiations in the green to red spectral range in the phosphor compounds 120 or the phosphor bodies 125 formed therefrom. By way of example, a white mixed radiation may be generated in this way. The color locus of the light radiation emitted by a phosphor body 125 is dependent on the ratio of converted to unconverted radiation, which for its part is dependent, inter alia, on the thickness of the relevant phosphor body 125.

The compressing of the phosphor compounds 120 is carried out with the aid of a suitable tool. The tool comprises two tool parts, which are moved relative to one another for the compressing of the phosphor compounds 120 and are thereby compressed. For the compressing, one tool part may be moved, or both tool parts may be jointly moved toward one another. The tool may be comprised by a compressing molding installation, for example.

Of the two tool parts, only one tool part 140 is shown in FIG. 3. The tool part 140, which comprises a planar shape in the area of a side provided for the compressing of the phosphor compounds 120, may be for example part of a flat mold tool of the compressing molding installation mentioned above. The carrier 100 is arranged on the further tool part (not shown) prior to the compressing. The carrier 100 may be brought to a state upside down in comparison with FIG. 2 for the compressing, as is shown in FIG. 3. The droplet-shaped phosphor compounds 120 may adhere on the carrier 100 in this position.

During the operation of the tool, the phosphor compounds 120 are pressed flat between the tool part 140 comprising the areal planar pressing side and the carrier 100. In this case, the phosphor compounds 120 simultaneously spread out laterally. In this way, phosphor bodies 125 comprising planar front sides and sharp front edges are shaped from the phosphor compounds 120. In FIG. 3, the front sides are the downwardly directed sides of the phosphor bodies 125. Each semiconductor chip 110 is encapsulated by a dedicated phosphor body 125. The bond wires 115 may be completely surrounded by the phosphor bodies 125.

As was indicated above, the color locus of the light radiation emitted by a phosphor body 125 during the operation of the associated semiconductor chip 110 depends on the material thickness of the phosphor body 125. Since the phosphor compounds 120 are jointly compressed, all phosphor bodies 125 formed thereby may comprise substantially the same shape and the same thickness. In this way, all phosphor bodies 125 may emit a light radiation comprising substantially the same color locus, and only low color locus scattering may therefore be present with regard to the light radiations emittable by the phosphor bodies 125 of the carrier 100.

The compressing may furthermore be carried out in such a way that all light radiations emittable by the phosphor bodies 125 during the operation of the semiconductor chips 110 comprise on average a predefined color locus or predefined color space coordinates (CIE color space). Various procedures are conceivable for this purpose.

A certain degree of color locus regulation may be achieved by the phosphor compounds 120 being compressed to a predefined material thickness. For this purpose, consideration may be given to a distance regulation, for example. In this case, the tool parts of the tool used for the compressing may be moved until the tool parts or pressing sides of the tool parts that are situated opposite one another are at a predefined distance.

It is also possible to use spacers that may form a mechanical stop during the compressing of the phosphor compounds 120. Such spacers may be provided (not illustrated) for example on the carrier 100 or on the tool part 140.

A further possibility, which may be realized as an alternative or in addition to the distance regulation, is an inline color locus measurement carried out during the compressing. In this case, a plurality or all of the semiconductor chips 110 may be operated and the light radiation emitted by the phosphor compounds 120 may be detected. During the compressing of the phosphor compounds 120, a shift in the ratio of converted to unconverted radiation, and thus a color locus shift, takes place. The compressing is carried out on the basis thereof until the measured light radiation comprises a color locus corresponding to a predefined color locus. Carrying out such a measurement requires the use of a device for energizing the carrier 100 or the semiconductor chips 110 and a measuring device for detecting the light radiation (not illustrated). The measuring device may be arranged outside the tool used for the compressing. In order that the light radiation may pass through the tool and reach the measuring device, component parts of the tool such as the tool part 140 may be configured such that they are radiation-transmissive at least regionally.

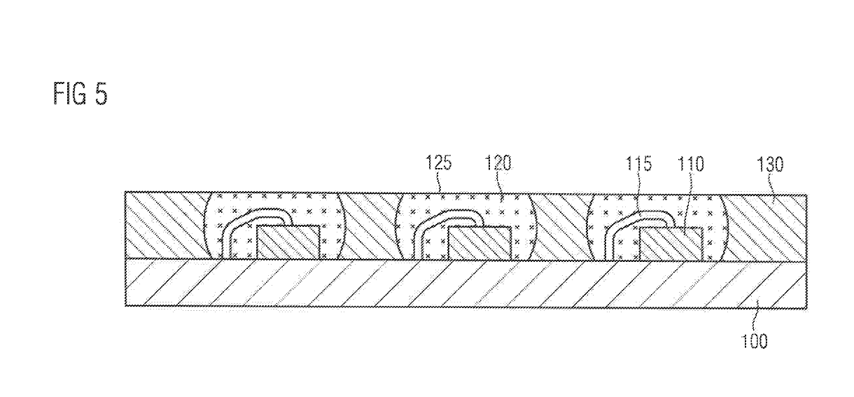

The compressing is followed by curing of the phosphor compounds 120 or of the phosphor bodies 125 formed therefrom. A further step is removal from the mold, that is to say removal of the carrier 100 from the tool used for the compressing. The tool parts are moved away from one another beforehand, in order to open the tool. After removal from the mold, the carrier 100 is present in the state shown in FIG. 4, in which each semiconductor chip 110 is surrounded by a dedicated cured phosphor body 125. The phosphor bodies 125 comprise planar front sides and sharp edges present at the margin of the front side. Interspaces are present between the phosphor bodies 125. In this state, operation of a semiconductor chip 110 has the consequence that a light radiation is emitted not only via a front side of the associated phosphor body 125 but also laterally from the phosphor body 125. Depending on the application, it may be desirable for emission of light to take place only via the front side.

In order to achieve this, subsequently, as is shown in FIG. 5, a reflective compound 130 may be applied on the carrier 100 in the interspaces between the phosphor bodies 125, such that the phosphor bodies 125 are circumferentially surrounded by the reflective compound 130. The reflective compound 130 may achieve the effect that a light radiation emitted laterally from the phosphor bodies 125 is reflected and, therefore, emission of radiation may take place only via the front sides of the phosphor bodies 125.

The reflective compound 130 may comprise for example silicone with TiO2 particles contained therein. The reflective compound 130 is applied in a flowable state on the carrier 100 and then cured. The application may be carried out by the potting of the interspaces between the phosphor bodies 125. Since the phosphor bodies 125 comprise sharp front edges, the potting may be carried out reliably without the front sides of the phosphor bodies 125 being wetted.

Further steps (not shown) may be carried out after that. They include, for example, a singulation process in which the carrier comprising the construction shown in FIG. 5 is singulated by severing at predefined locations. Separate optoelectronic components or packages may be provided as a result. The singulation may be carried out in such a way that, for example, single-chip components separated from one another are formed in this way, which comprise in each case a part of the carrier 100, a semiconductor chip 110 and a phosphor body 125 circumferentially enclosed by the reflective compound 130 in the area of the semiconductor chip 110. It is also possible to form multi-chip components comprising a part of the carrier 100, a plurality of semiconductor chips 110 and a plurality of phosphor bodies 125 surrounded by the reflective compound 130.

Further embodiments of a method for producing optoelectronic components are described on the basis of the following figures. In this case, in a comparable manner, phosphor bodies 125 are formed by the compressing of phosphor compounds 120 in the area of semiconductor chips 110. It is pointed out that corresponding processes and identical and identically acting component parts will not be discussed in detail again below. For details in respect thereof, reference is instead made to the above description. Furthermore, it is pointed out that features and details mentioned with regard to one of the following embodiments may also apply to other embodiments. A combination of features of a plurality of embodiments is also possible.

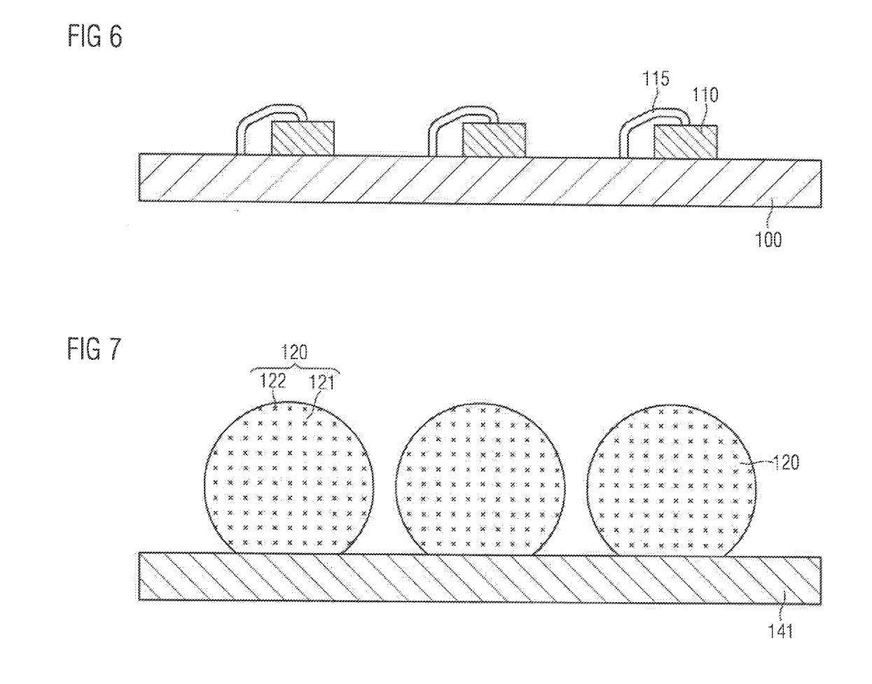

FIGS. 6 to 10 show process steps which may be carried out in a further method for producing optoelectronic components. As is shown in FIG. 6, a plurality of optoelectronic semiconductor chips 110 are arranged on the carrier substrate 100. In a departure from the method in FIGS. 1 to 5, ball- or bump-shaped phosphor compounds 120 are applied on an auxiliary carrier 141 prior to their compressing, as is shown in FIG. 7. The auxiliary carrier 141 may comprise Teflon, for example. The auxiliary carrier 141 comprises a planar shape in the area of the side on which the phosphor compounds 120 are arranged and with which the phosphor compounds 120 are subsequently compressed. The phosphor compounds 120 are metered onto the auxiliary carrier 141 in a predefined grid corresponding to a grid of the semiconductor chips 110 on the carrier 100. The phosphor compounds 120 may be applied with the aid of a suitable process, for example dispensing, screen printing or stencil printing.

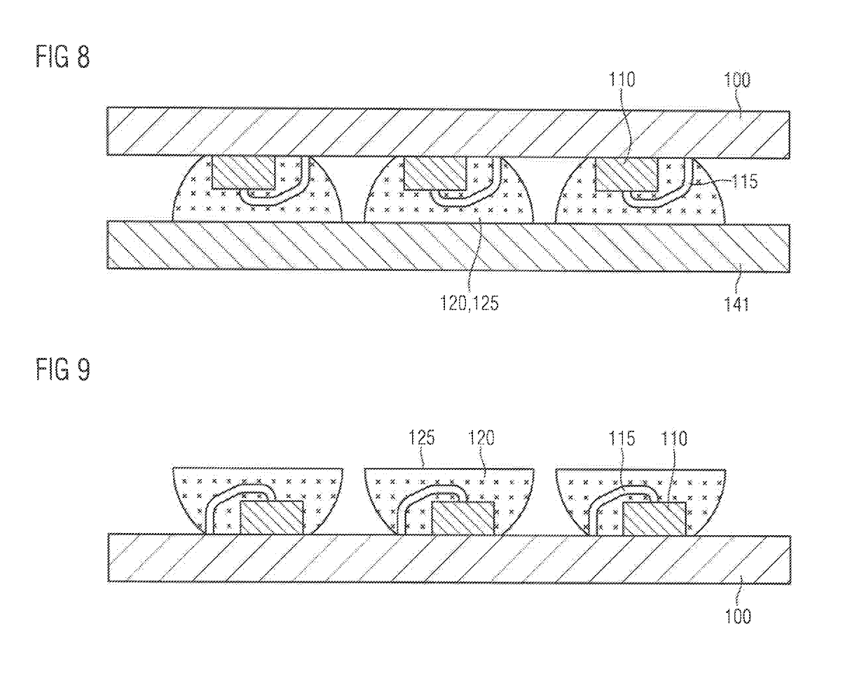

The compressing of the phosphor compounds 120 for forming phosphor bodies 125, which is shown in FIG. 8, is carried out with the aid of a tool (not shown). The tool, which may be comprised by a compressing molding installation, comprises two tool parts. For the compressing, the carrier 100 provided with the semiconductor chips 110 and the auxiliary carrier 141 provided with the phosphor compounds 120 are arranged on the tool parts of the tool. Afterward, the tool parts and, as a result, the carrier 100 and the auxiliary carrier 141 are moved relative to one another. This results in the semiconductor chips 110 being dipped into the uncured phosphor compounds 120 and the phosphor compounds 120 being pressed flat between the carrier 100 and the auxiliary carrier 141 comprising the planar pressing side. Here as well, as is shown in FIG. 8, the carrier 100 may be present in an upside down state.

The phosphor compounds 120 may be compressed to a predefined material thickness during this process by means of a distance regulation. In the case where spacers are used, the latter may also be arranged (not illustrated) on the auxiliary carrier 141. Alternatively or additionally, a color locus measurement may be carried out. For this purpose, the auxiliary carrier 141 may be configured such that it is radiation-transmissive at least regionally.

That may be followed by curing of the phosphor compounds 120 or of the phosphor bodies 125 formed therefrom, removal from the mold or removal of the carrier 100 together with the auxiliary carrier 141 from the tool, and detachment of the auxiliary carrier 141, as a result of which the carrier 100 may be present in the state shown in FIG. 9. The phosphor bodies 125 comprise planar front sides and sharp front edges.

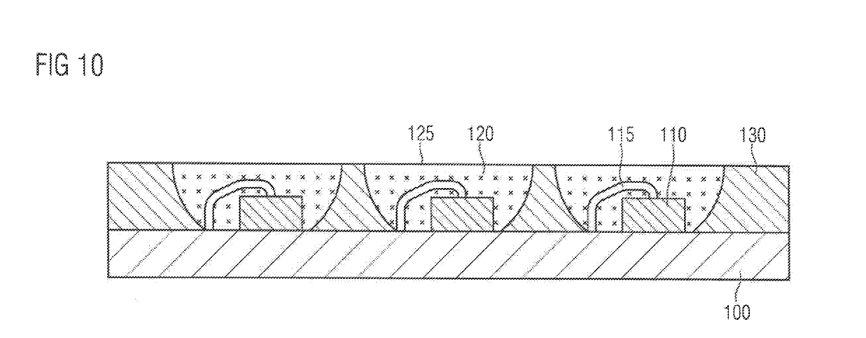

Afterward, as is shown in FIG. 10, a reflective compound 130 may be applied on the carrier 100 in interspaces between the phosphor bodies 125, such that the phosphor bodies 125 are circumferentially surrounded by the reflective compound 130. This may be carried out by potting. In this case, the sharp front edges of the phosphor bodies 125 may prevent wetting of the front sides. After curing of the reflective potting compound 130, a singulation process may furthermore be carried out.

The compressing of the phosphor compounds 120 using the auxiliary carrier 141 previously provided with the phosphor compounds 120 makes it possible that as a result phosphor bodies 125 are formed which comprise a shape at least partly widening in the direction of the front side (see FIG. 9). As a result, the subsequently formed reflective compound 130 or side walls of the reflective compound 130 which are adjacent to the phosphor bodies 125 circumferentially may serve as reflectors for directing light radiation in the direction of the front sides of the phosphor bodies 125. This may also apply, if appropriate, with regard to the phosphor bodies 125 produced in accordance with the method in FIGS. 1 to 5.

It is possible for the phosphor compounds 120 not only to be pressed flat, in order in this way, as was described above, to form phosphor bodies 125 comprising planar front-side surfaces and sharp edges. It is also possible at least partly to impart a predefined shape to the phosphor compounds 120. This may be achieved by virtue of the fact that a component part used for the compressing comprises a structured side or a side comprising a structure. This may be taken into consideration in particular for an auxiliary carrier. In this case, the phosphor compounds 120, prior to the compressing, may be applied on the auxiliary carrier as accurately as possible with respect to the shaping structure. Possible embodiments, which constitute modifications of the method described with reference to FIGS. 6 to 10, are described in greater detail with reference to the following figures.

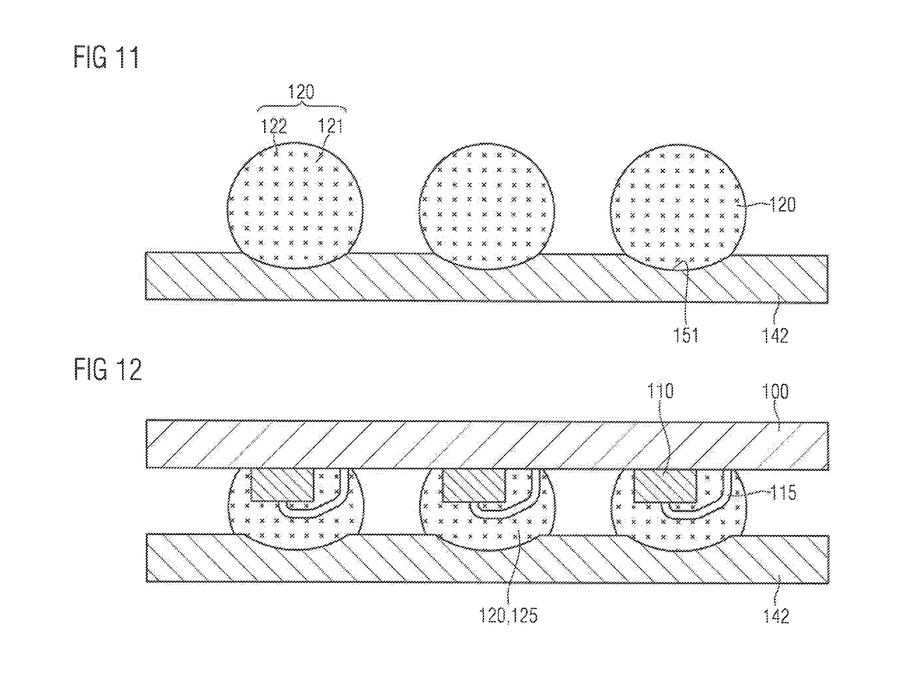

FIGS. 11 to 14 show a further process sequence that may be employed during the production of optoelectronic components. In this case, as is shown in FIG. 11, phosphor compounds 120 are arranged on an auxiliary carrier 142 prior to the compressing. The auxiliary carrier 142 comprises structure elements in the form of curved depressions 151 in the area of the side on which the phosphor compounds 120 are arranged and with which the phosphor compounds 120 are subsequently compressed. The depressions 151 may comprise a circular contour, for example, in plan view. The phosphor compounds 120 are positioned at these locations. The depressions 151 and consequently the phosphor compounds 120 applied here are arranged in a grid corresponding to a grid of the semiconductor chips 110 on the carrier 100.

The carrier 100 provided with the semiconductor chips and the auxiliary carrier 142 provided with the phosphor compounds 120 are subsequently arranged on tool parts of a tool (not shown), and are compressed with the aid of the tool, as is shown in FIG. 12. This results in the semiconductor chips 110 being dipped into the phosphor compounds 120 and the phosphor compounds 120 being compressed. The compressing may again be carried out to a predefined material thickness. Alternatively or additionally, a color locus measurement may be carried out.

The phosphor bodies 125 formed by the compressing of the phosphor compounds 120 comprise, owing to the structure of the auxiliary carrier 142 comprising the depressions 151, front-side surfaces matched thereto which are curved outward or convexly. On account of this shape, the phosphor bodies 125 may act as lenses in the components produced.

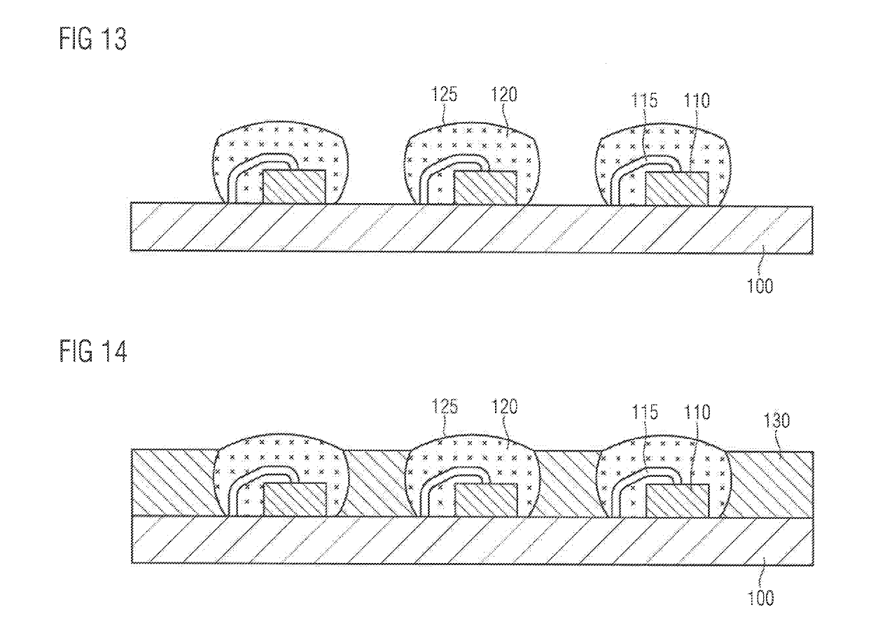

After the compressing, further steps such as the curing of the phosphor bodies 125 and removal from the mold are carried out, as a result of which the carrier 100 may be provided in the state shown in FIG. 13. Afterward, as is shown in FIG. 14, a reflective compound 130 may be applied on the carrier 100 in interspaces between the phosphor bodies 125, such that the phosphor bodies 125 are circumferentially surrounded by the reflective compound 130. This may be carried out by potting. The phosphor bodies 125 comprising the curved front sides also comprise sharp front-side edges that may prevent wetting of front sides. After curing of the potting compound 130, a singulation process may be carried out.

FIGS. 15 to 18 show a further process sequence that may be employed during the production of optoelectronic components. In this case, as is shown in FIG. 15, phosphor compounds 120 are applied on an auxiliary carrier 143 prior to the compressing. The auxiliary carrier 143 comprises a structure in the form of cavities 152, said structure being provided for shaping, in the area of the side on which the phosphor compounds 120 are arranged and which is used for the subsequent compressing. The cavities 152 are delimited by web-shaped elevations that form side walls of the cavities 152. The cavities 152 are planar at the bottom. The cavities 152 may comprise a circular contour, for example, in plan view.

The phosphor compounds 120 are applied on the auxiliary carrier 143 in such a way that the phosphor compounds 120 are situated at least partly in the cavities 152. In this case, as is indicated in FIG. 15, the phosphor compounds 120 may also project partly from the cavities 152. The cavities 152 and, consequently, the phosphor compounds 120 applied on the auxiliary carrier 143 are arranged in a grid corresponding to a grid of the semiconductor chips 110 on the carrier 100.

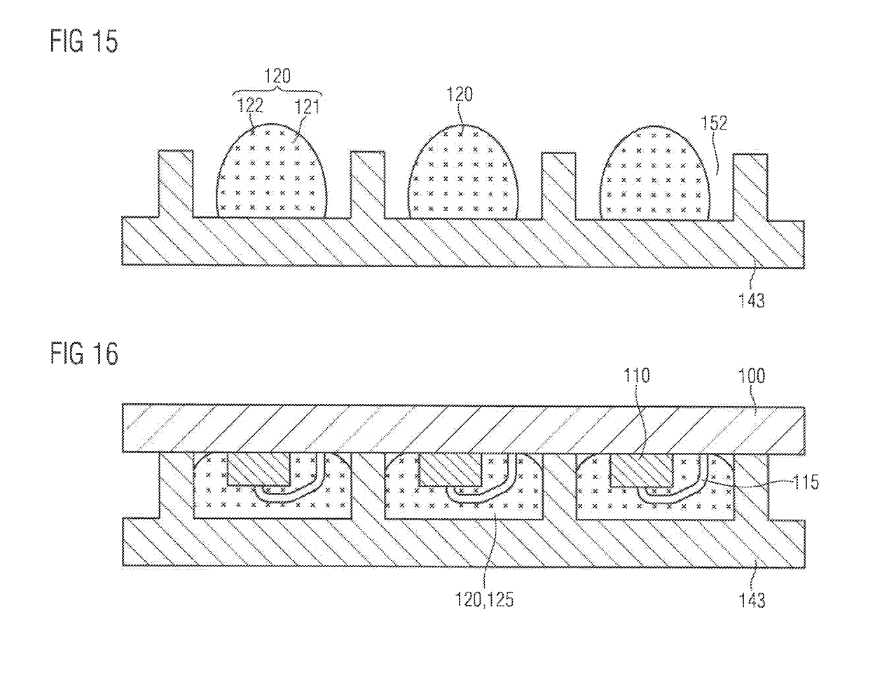

The carrier 100 provided with the semiconductor chips and the auxiliary carrier 143 provided with the phosphor compounds 120 are subsequently arranged on tool parts of a tool (not shown), and are compressed with the aid of the tool, as is shown in FIG. 16. This is associated with the semiconductor chips 110 being introduced into the phosphor compounds 120 and cavities 152, and with the phosphor compounds 120 being compressed. This process may be carried out until the carrier 100 and the elevations delimiting the cavities 152 touch one another, as is likewise shown in FIG. 16. The elevations may thus serve as spacers for providing a mechanical stop, as a result of which the phosphor compounds 120 may be compressed to a predefined material thickness. Additionally or alternatively, a color locus measurement may be carried out if appropriate.

During the compressing, the phosphor compounds 120 are also matched to the shape of the cavities 152 of the auxiliary carrier 143. The phosphor bodies 125 formed as a result, which do not completely fill the cavities 152 in the present case, comprise planar front sides and sharp front edges. Adjacently to the front side, the phosphor bodies 125 comprise a marginal area predefined by the cavities 152 and comprising flanks running perpendicular to the front side in cross section. In the case of cavities 152 comprising a circular contour in plan view, the marginal area of the phosphor bodies 125 may be present in each case in the form of a lateral surface extending circumferentially in a circular-cylindrical fashion. The phosphor bodies 125 not completely filling the cavities 152 may comprise a widening geometry in a area adjacent to the carrier 100, as a result of which reflectors may be formed at this location.

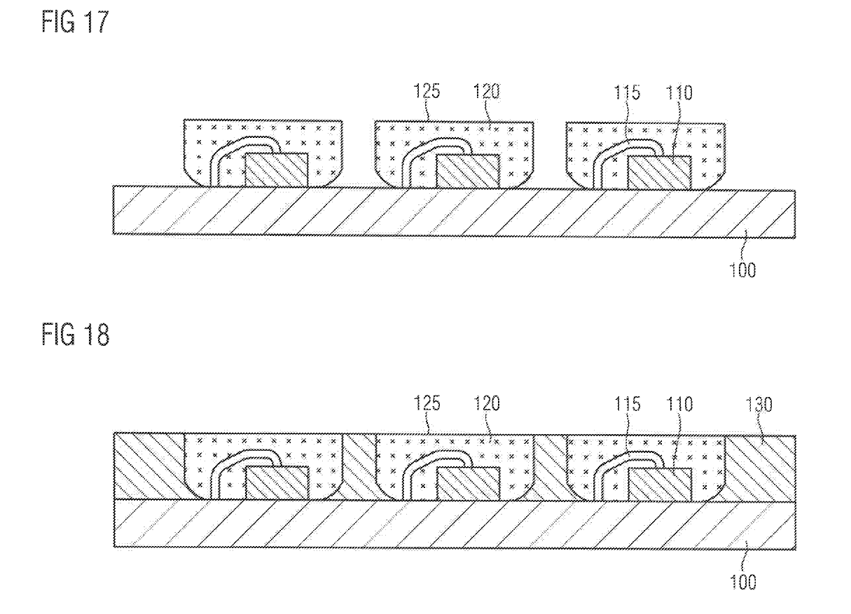

Further steps such as the curing of the phosphor bodies 125 and removal from the mold are subsequently carried out, as a result of which the carrier 100 may be provided in the state shown in FIG. 17. Afterward, as is shown in FIG. 18, a reflective compound 130 may be applied, for example by potting, on the carrier 100 in interspaces between the phosphor bodies 125. The sharp front edges of the phosphor bodies 125 may prevent wetting of front sides. After curing of the reflective compound 130, singulation may be carried out.

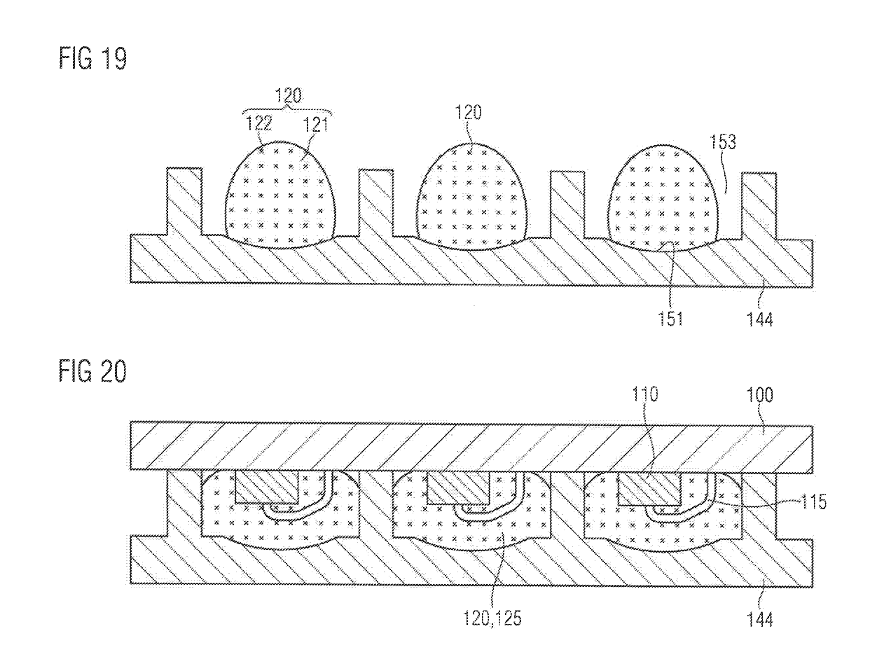

FIGS. 19 to 22 show a further process sequence, in which, as is shown in FIG. 19, phosphor compounds 120 are applied on an auxiliary carrier 144 prior to the compressing. The auxiliary carrier 144 comprises a structure in the form of cavities 153 in the area of the side on which the phosphor compounds 120 are arranged and which is used for the compressing. The cavities 153 are delimited by web-shaped elevations that form side walls of the cavities 153. The cavities 153 comprise curved depressions 151 at the bottom. The structure of the auxiliary carrier 144 may be regarded as a combination of the structures of the auxiliary carriers 142, 143 described above. The cavities 153 and depressions 151 may comprise a circular contour, for example, in plan view. The phosphor compounds 120 are applied on the auxiliary carrier 144 in such a way that the phosphor compounds 120 are situated in the area of the cavities 153. The cavities 153 and hence the phosphor compounds 120 are arranged in a grid corresponding to a grid of the semiconductor chips 110 on the carrier 100.

The carrier 100 and the auxiliary carrier 144 are subsequently arranged on tool parts of a tool (not shown), and are compressed with the aid of the tool, as is shown in FIG. 20. This is associated with the semiconductor chips 110 being introduced into the phosphor compounds 120 and cavities 153, and with the phosphor compounds 120 being compressed. In this case, too, the elevations of the auxiliary carrier 144 that surround the cavities 153 may serve as spacers. Alternatively or additionally, a color locus measurement may be carried out if appropriate.

The phosphor bodies 125 formed by the compressing of the phosphor compounds 120 once again do not completely fill the cavities 153. The phosphor bodies 125 comprise front-side surfaces which are predefined by the depressions 151 and which are curved outward. Sharp front edges are also present. Adjacently to the front side, the phosphor bodies 125 comprise a marginal area predefined by the cavities 153. In the case of cavities 153 comprising a circular contour in plan view, the marginal area may be present in the form of a lateral surface extending circumferentially in a circular-cylindrical fashion.

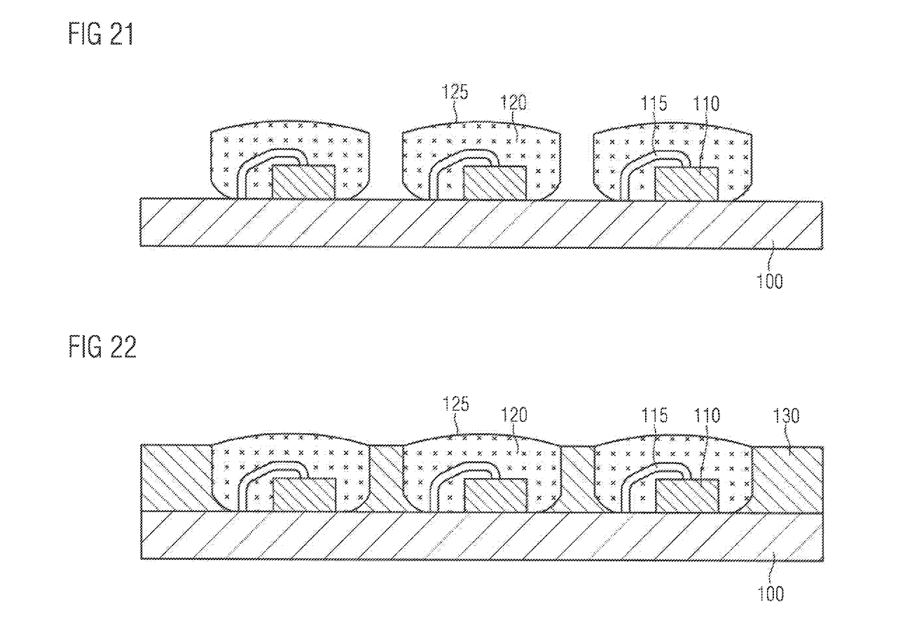

This is followed by curing of the phosphor bodies 125 and removal from the mold, as a result of which the carrier 100 may be provided in the state shown in FIG. 21. Afterward, as is shown in FIG. 22, a reflective compound 130 may be applied, for example by potting, on the carrier 100 in interspaces between the phosphor bodies 125. The sharp front edges of the phosphor bodies 125 may prevent wetting of front sides. After curing of the reflective compound 130, singulation may be carried out.

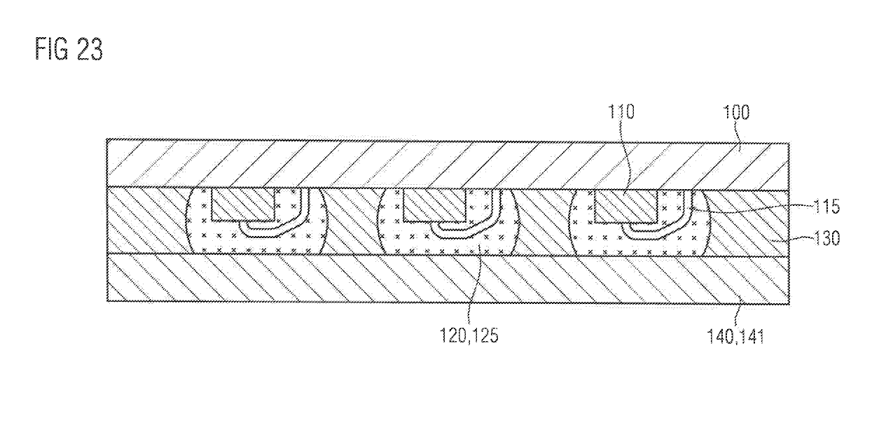

In the embodiments described above, the process of forming a reflective compound 130 takes place after removal from the mold. In a departure from this, the process of forming the reflective compound 130 may also be carried out prior to removal from the mold, as is illustrated in FIG. 23. If the phosphor compounds 120 are compressed between the carrier 100 and the tool part 140, as was explained above with reference to FIG. 3, the reflective compound 130 in this case, after curing of the phosphor bodies 125 formed as a result, is introduced into cavities present between the carrier 100, the phosphor bodies 125 and the tool part 140. Such a procedure, which may involve a transfer molding process, likewise enables the reflective compound 130 to be applied without front sides of the phosphor bodies 125 being wetted. Afterward, the reflective compound 130 may be cured, and the carrier 100 provided with the reflective compound 130 may be removed from the tool and singulated.

For the case where the phosphor compounds 120 are compressed between the carrier 100 and the auxiliary carrier 141, as was explained above with reference to FIG. 8, the reflective compound 130, after curing of the phosphor bodies 125 formed as a result, is introduced into cavities present between the carrier 100, the phosphor bodies 125 and the auxiliary carrier 141. Steps such as curing of the reflective compound 130, removal of the carrier 100 together with the auxiliary carrier 141 from the tool, detachment of the auxiliary carrier 141, and singulation may subsequently be carried out. A comparable procedure may also be taken into consideration when using the structured auxiliary carrier 142 (see FIG. 12).

The embodiments explained with reference to the figures constitute preferred and/or exemplary embodiments of the invention. Besides the embodiments described and depicted, further embodiments are conceivable which may comprise further modifications and/or combinations of features. It is possible, for example, to use other materials instead of materials indicated above. Furthermore, above indications concerning colors of light radiations may be replaced by other indications.

With regard to further materials, consideration may be given to the case where the particles 122 contained in the basic material 121 comprise further particles in addition to phosphor particles. These may include, besides the scattering particles mentioned above, for example reflective particles and pigments. It is possible for the basic material 121 to contain different particles 122. Scattering particles may influence the luminous properties of an optoelectronic component and enable for example light mixing in a molded or phosphor body 125. By means of reflective particles, a white body color may be imparted to a molded or phosphor body 125. A different body color may be brought about with the aid of inorganic pigments.

The method or the embodiments explained with reference to the figures and their possible modifications may also be carried out using molding compounds 120 that do not comprise any phosphor particles. Such phosphor-free molding compounds 120 may likewise comprise a radiation-transmissive basic material 121, for example silicone. In the basic material 121 it is possible for particles 122, for example scattering particles, reflective particles, and/or pigments, to be embedded or else not embedded. Consideration may be given to such configurations, for example, in order, after the formation of molded bodies 125, to use the shape thereof for producing reflectors with the aid of a reflective compound 130.

Other optoelectronic semiconductor chips for generating a light radiation may be employed instead of the semiconductor chips 110 described. By means of example, semiconductor chips comprising two front-side contacts may be used. Such semiconductor chips may be fixed on a carrier 100 by adhesive bonding. The front-side contacts may be connected to mating contacts of the carrier 100 with the aid of bond wires 115. The use of semiconductor chips comprising two rear-side contacts is furthermore possible. Via the rear-side contacts, such semiconductor chips may be mechanically and electrically connected to mating contacts of a carrier 100, for example using a solder or conductive adhesive. In a further variant, semiconductor chips configured as volume emitters may be used.

In a departure from the structures for shaping molding or phosphor compounds 120 as described and shown in the figures, consideration may be given to other structures. By way of example, an auxiliary carrier comprising cavities may be used, wherein the cavities comprise an at least partly widening geometry proceeding from a bottom area. As a result, it is possible to form molded or phosphor bodies 125 comprising a predefined shape at least partly widening in the direction of the front side.

With regard to the use of structures, consideration may furthermore be given to using non-uniform structures, that is to say that different structure elements are provided on an auxiliary carrier. In this way, by means of the compressing of molding compounds 120, it is possible to produce molded or phosphor bodies 125 comprising different shapes on a carrier 100.

It is furthermore possible to use for the compressing of molding or phosphor compounds 120 a tool part comprising a structure in the area of the side provided for the compressing. The same structures as have been shown and described with regard to auxiliary carriers may be used for such a tool part. In this sense, for example, the component parts 142, 143, 144 shown in FIGS. 12, 16, 20 may also be tool parts that are used for the compressing of the molding compounds 120 previously applied on the carrier 100.

With regard to a tool part, it is furthermore possible to apply molding compounds 120 thereto prior to the compressing, such that in a manner comparable with the use of an auxiliary carrier, in the context of the compressing, semiconductor chips 110 may be dipped into the molding compounds 120.

In a further possible variant, formation of a reflective compound 130 may be omitted. In this configuration, singulation of the carrier 100 into single- or multi-chip components may be carried out after removal from the mold.

Although the invention has been more specifically illustrated and described in detail by means of preferred exemplary embodiments, nevertheless the invention is not restricted by the examples disclosed, and other variations may be derived therefrom by the person skilled in the art, without departing from the scope of protection of the invention.

1.-14. (canceled)

15. A method for producing an optoelectronic component, the method comprising:
arranging a plurality of optoelectronic semiconductor chips on a carrier; and
commonly compressing separate molding compounds in areas of the optoelectronic semiconductor chips, wherein separate molded bodies are formed in the areas of the optoelectronic semiconductor chips.

16. The method according to claim 15, further comprising applying the molding compounds on the carrier in the areas of the optoelectronic semiconductor chips prior to compressing.

17. The method according claim 15, wherein compressing comprises using a tool part having a planar shape in an area of a side provided for compressing the molding compounds.

18. The method according to claim 15, wherein compressing comprises using a tool part having structures in an area of a side provided for compressing the molding compounds.

19. The method according to claim 15, further comprising applying the molding compounds on an auxiliary carrier prior to compressing.

20. The method according to claim 19, wherein the auxiliary carrier comprises structures in an area of a side provided for compressing the molding compounds.

21. The method according to claim 15, further comprising curing the molding compounds after compressing.

22. The method according to claim 15, wherein the molding compounds comprise a basic material and particles from the following group: phosphor particles for radiation conversion, scattering particles, reflective particles and/or pigments.

23. The method according to claim 15, further comprising applying a reflective compound on the carrier in such a way that the molded bodies are surrounded circumferentially by the reflective compound.

24. The method according to claim 15, wherein the molding compounds are compressed to a predefined material thickness.

25. The method according to claim 15, further comprising operating at least one optoelectronic semiconductor chip and detecting a light radiation while compressing the molding compounds.

26. The method according to claim 25, wherein the molding compounds are phosphor compounds effecting a radiation conversion, wherein a shift in a color locus of the detected light radiation takes place while compressing the phosphor compounds, and wherein compressing the phosphor compounds is carried out until the detected light radiation comprises a color locus corresponding to a predefined color locus.

27. The method according to claim 25, wherein component parts of a tool used for compressing and/or of an auxiliary carrier used are configured such that they are radiation-transmissive at least regionally.

28. The method according to claim 15, wherein each molded body, formed by compressing each molding compound, comprises a shape that widens at least partly in a direction of a front side.

29. A method for producing an optoelectronic component, the method comprising:
arranging a plurality of optoelectronic semiconductor chips on a carrier;
commonly compressing separate molding compounds in areas of the optoelectronic semiconductor chips, wherein separate molded bodies are formed in the areas of the optoelectronic semiconductor chips; and
operating at least one optoelectronic semiconductor chip and detecting a light radiation while compressing the molding compounds, wherein the molding compounds are phosphor compounds effecting a radiation conversion.

30. A method for producing an optoelectronic component, the method comprising:
arranging a plurality of optoelectronic semiconductor chips on a carrier;
commonly compressing separate molding compounds in areas of the optoelectronic semiconductor chips, wherein separate molded bodies are formed in the areas of the optoelectronic semiconductor chips; and
applying a reflective compound on the carrier in such a way that the molded bodies are surrounded circumferentially by the reflective compound, wherein each molded body, formed by compressing each molding compound, comprises a shape that widens at least partly in a direction of a front side thereby enabling the reflective compound to act as a reflector for directing light radiation in the direction of the front side of the molded bodies.
